(19) United States
(12) Patent Application Publication
(10) Pub. No.: US 2026/0076045 A1
(43) Pub. Date: Mar. 12, 2026

(54) DISPLAY DEVICE AND DISPLAY PANEL

(71) Applicant: LG Display Co., Ltd., Seoul (KR)

(72) Inventors: SUKHYUN KANG, Paju-si (KR); DONGIL CHU, Paju-si (KR); JUYOUNG PARK, Paju-si (KR)

(73) Assignee: LG Display Co., Ltd., Seoul (KR)

(21) Appl. No.: 19/244,912

(22) Filed: Jun. 20, 2025

(30) Foreign Application Priority Data
Sep. 9, 2024 (KR) 10-2024-0122394

(51) Int. Cl. H10K 59/126; H10K 59/40; H10K 102/00

(52) U.S. Cl. CPC H10K 59/126; H10K 59/40; H10K 2102/351

(57) ABSTRACT

A display panel and a display device are discussed. The display device can include a through hole disposed in a display area and allowing an optical electronic device to be disposed, an emission layer cutting pattern formed in an surrounding area outside of the through hole to block moisture from entering the display area through the through hole, and a shielding layer disposed under the emission layer cutting pattern. The shielding layer includes at least one open area disposed at at least one location corresponding to the structure of the emission layer cutting pattern.

### CROSS-REFERENCE TO RELATED APPLICATION

This application claims priority to Korean Patent Application No. 10-2024-0122394, filed in the Republic of Korea on Sep. 9, 2024, the entire contents of which is hereby expressly incorporated by reference for all purposes as if fully set forth herein into the present application.

### BACKGROUND

### Technical Field

The present disclosure relates to a display device and a display panel, and more particularly, to a display device and a display panel that include an emission layer cutting pattern formed for effectively preventing moisture from penetrating a through hole where an optical electronic device is located.

### Discussion of the Related Art

As display devices for displaying images using digital data, liquid crystal display (LCD) devices using liquid crystals, organic light emitting display devices using organic light emitting diodes (OLED), and the like are widely used.

Among these display devices, the organic light emitting display device using an organic light emitting diode, which is a self-emission element, has the features of fast response speed, high contrast ratio, high luminous efficiency, high luminance, wide viewing angle, and the like. For example, the light emitting diode can be implemented with an inorganic or organic material.

Organic light emitting display devices can include an organic light emitting diode disposed in each of a plurality of subpixels SP disposed in a display panel. Image displaying by light emitted from the organic light emitting diodes can be performed by controlling current flowing through, or voltage applied to, the organic light emitting diodes. In this way, as luminance from each subpixel is controlled, the organic light emitting display devices can display images.

Recent advances in display technology have enabled display devices to provide increased functions, such as an image capture function, a sensing function, and the like, as well as an image display function. To provide these functions, a display device can need to include an optical electronic device, such as a camera, a light receiving device, a sensor for detecting an image, and the like.

To receive light passing through a front surface of a display device, it can be desirable for such an optical electronic device to be located in an area of the display device where incident light coming from the front surface can be increasingly received and detected. Work has been progressing on placing an optical electronic device in a through hole formed in an active area where subpixels are disposed.

Here, a portion of the active area where a through hole for placing an optical electronic device is disposed can be referred to as a hole-in-active area (HiAA).

In this implementation, moisture can penetrate the through hole where the optical electronic device is located, and thereby, the performance of light emitting elements included in the subpixels disposed in the active area can be degraded.

For example, to block moisture penetrating a through hole where an optical electronic device is located, an emission layer between a through hole and a normal area can be cut, and thereby, an emission layer cutting pattern can be disposed between the through hole and the normal area.

To form such an emission layer cutting pattern, in the process in which laser beams are radiated between the through hole and the normal area, a phenomenon in which one or more metal layers are burred or raised due to a difference in energy intensities can occur.

### SUMMARY OF THE DISCLOSURE

To address these issues, inventors of the present application have invented a display device and a display panel that include an emission layer cutting pattern formed for effectively preventing moisture from penetrating a through hole where an optical electronic device is located.

One or more aspects of the present disclosure can provide a display device and a display panel that include a structure where a shielding layer corresponding to a structure of an emission layer cutting pattern between a through hole and a normal area is disposed, and thereby, are capable of preventing a defect in which a metal layer is burred (e.g., an edge of the metal layer is raised) on the surface of the metal layer during the process of forming the emission layer cutting pattern.

One or more aspects of the present disclosure can provide a display device and a display panel that include a structure where a sacrifice layer and a shielding layer corresponding to a structure of an emission layer cutting pattern between a through hole and a normal area are disposed, and thereby, are capable of effectively disposing the emission layer cutting pattern and preventing moisture from penetrating the through hole.

According to one or more example embodiments of the present disclosure, a display device can include a display panel having a through hole disposed in a display area, an optical electronic device disposed so that at least part of the optical electronic device overlaps with the through hole, and a driving circuit configured to control the display panel, where the display panel includes at least one emission layer cutting pattern disposed in an surrounding area outside of the through hole to block moisture from entering the display area through the through hole, and a shielding layer disposed under the at least one emission layer cutting pattern and including at least one open area disposed at at least one location corresponding to the structure of the at least one emission layer cutting pattern.

According to one or more example embodiments of the present disclosure, a display panel can include a through hole disposed in a display area and allowing an optical electronic device to be disposed, at least one emission layer cutting pattern formed in an surrounding area outside of the through hole to block moisture from entering the display area through the through hole, and a shielding layer disposed under the at least one emission layer cutting pattern and having at least one open area disposed at at least one location corresponding to the structure of the at least one emission layer cutting pattern.

According to one or more aspects of the present disclosure, a display device and a display panel can include an emission layer cutting pattern, and thereby, provide an effect or advantage of effectively preventing moisture from penetrating a through hole.

According to one or more aspects of the present disclosure, a display device and a display panel can include a structure where a shielding layer corresponding to a structure of an emission layer cutting pattern between a through hole and a normal area is disposed, and thereby, provide an effect or advantage of preventing a defect in which a metal layer is burred (e.g., an edge of the metal layer is raised) on the surface of the metal layer during the process of forming the emission layer cutting pattern and implementing process optimization.

According to one or more aspects of the present disclosure, a display device and a display panel can include a structure where a sacrifice layer and a shielding layer corresponding to a structure of an emission layer cutting pattern between a through hole and a normal area are disposed, and thereby, provide an effect or advantage of effectively preventing moisture from penetrating the through hole.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIG. 1 illustrates an example display device according to aspects of the present disclosure;

FIG. 2 illustrates an example system configuration of the display device according to aspects of the present disclosure;

FIG. 3 illustrates an example equivalent circuit of each, or one or more, of subpixels included in a display panel according to aspects of the present disclosure;

FIG. 4 illustrates example subpixel arrangements in three areas included in a display area of the display panel according to aspects of the present disclosure;

FIG. 5 is an example cross-sectional view of a portion of the display area in the display panel according to aspects of the present disclosure;

FIG. 6 is an example plan view of an optical area in the display panel according to aspects of the present disclosure;

FIG. 7 is an example cross-sectional view of the optical area in the display panel according to aspects of the present disclosure;

FIGS. 8A and 8B illustrate a comparison of a defect in which a metal layer is burred on the surface of the metal layer in an example where a shielding layer having a structure corresponding to a structure of an emission layer cutting pattern is present and an example where such a shielding layer is absent, in the display panel according to aspects of the present disclosure;

FIGS. 9 and 10 illustrate an example process of forming the display panel according to aspects of the present disclosure;

FIG. 11 is an example cross-sectional view of a shielding layer in the display panel according to aspects of the present disclosure;

FIG. 12 is a cross-sectional view of another example structure of a surrounding area outside of a through hole in the display panel according to aspects of the present disclosure; and

FIGS. 13 and 14 illustrate another example process of forming the display panel according to aspects of the present disclosure.

### DETAILED DESCRIPTION OF THE EMBODIMENTS

Hereinafter, some embodiments of the present disclosure will be described in detail with reference to exemplary drawings. Reference will now be made in detail to example embodiments of the present disclosure, examples or aspects of which can be illustrated in the accompanying drawings.

In the following description, the structures, implementations, methods, and operations described herein are not limited to the specific examples, aspects, and embodiments set forth herein and can be changed as is known in the art, unless otherwise specified. Like reference numerals designate like elements throughout, unless otherwise specified. Names of the respective elements used in the following explanations are selected only for convenience of writing the disclosure and can thus be different from those used in actual products. Advantages and features of the present disclosure, and implementation methods thereof will be clarified through following example embodiments described with reference to the accompanying drawings.

The present disclosure may, however, be embodied in different forms and should not be construed as limited to the example embodiments set forth herein. Rather, these example embodiments are provided so that this disclosure can be sufficiently thorough and complete to assist those skilled in the art to fully understand the scope of the present disclosure. Further, the protected scope of the present disclosure is defined by claims and their equivalents. In the following description, where the detailed description of the relevant known function or configuration can unnecessarily obscure aspects of the present disclosure, a detailed description of such known function or configuration can be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. Where the terms “comprise,” “have,” “include,” “contain,” “constitute,” “make up of,” “formed of,” and the like are used, one or more other elements can be added unless the term, such as “only,” is used. An element described in the singular form is intended to include a plurality of elements, and vice versa, unless the context clearly indicates otherwise.

Although the terms “first,” “second,” A, B, (a), (b), and the like can be used herein to describe various elements, these elements should not be interpreted to be limited by these terms as they are not used to define a particular order, sequence or precedence. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

Where positional relationships are described, for example, where the positional relationship between two parts is described using “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” another element or layer, a third element or layer can be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may” and vice versa.

Hereinafter, various embodiments of the present disclosure will be described in detail with reference to the accompanying drawings. All the components of each display device according to all embodiments of the present disclosure are operatively coupled and configured.

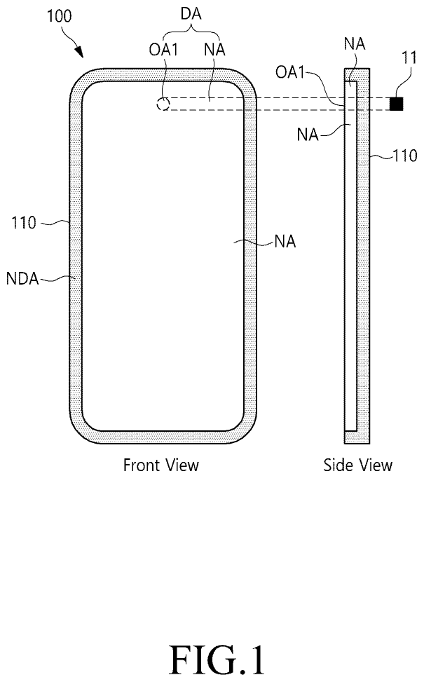

FIG. 1 illustrates an example display device according to aspects of the present disclosure.

Referring to FIG. 1, in one or more example embodiments, a display device 100 can include a display panel 110 for displaying images, and one or more optical electronic devices 11.

The display panel 110 can include a display area DA in which one or more images can be displayed and a non-display area NDA in which an image is not displayed. The display area DA can also be referred to as an active area. The non-display area NDA can surround the display area DA entirely or only in part(s).

A plurality of subpixels can be disposed in the display area DA, and several types of signal lines for driving the plurality of subpixels can be disposed in the display area DA.

The non-display area NDA can represent an area outside of the display area DA. Several types of signal lines can be disposed in the non-display area NDA, and several types of driving circuits can be connected to, or located in the non-display area NDA. At least a portion of the non-display area NDA can be bent, and thereby, be invisible from the front surface of the display device 100 or be covered by a case or housing of the display device 100. The non-display area NDA can be also referred to as a non-active area, a bezel, or a bezel area.

In one or more aspects, the one or more optical electronic devices 11 included in the display device 100 can be located under, or in a lower portion of, the display panel 110 (an opposite side to the viewing surface of the display panel 110).

In this implementation, light can enter the front surface (viewing surface) of the display panel 110, pass through the display panel 110, reach the one or more optical electronic devices 11 located under, or in the lower portion of, the display panel 110 (the opposite side to the viewing surface).

The one or more optical electronic devices 11 can be devices capable of receiving or detecting light passing through the display panel 110 and perform a predefined function based on the received light. For example, the one or more optical electronic devices 11 can include one or more of the following: an image capture device such as a camera (an image sensor), and/or the like; or a sensor such as a proximity sensor, an illuminance sensor, and/or the like.

In one or more aspects, the display area DA of the display panel 110 can include a normal area NA and one or more optical areas (OA1).

The one or more optical areas (OA1) can be one or more areas respectively overlapping with the one or more optical electronic devices 11.

In one or more aspects, the display area DA can include a normal area NA and a first optical area OA1. In this implementation, at least a portion of the first optical area OA1 can overlap with an optical electronic device 11.

When the display device 100 according to one or more aspects has a structure in which the optical electronic device 11 such as a camera, and the like, is located under, or in a lower portion of, the display panel 100 without being exposed to the outside, the display device 100 configured with this structure can be referred to as a display in which under-display camera (UDC) technology is implemented.

According to this implementation, the display device 100 can provide an advantage of preventing a reduction in the size of the display area DA because a notch or a camera hole for exposing a camera and the like need not be formed in the display panel 110.

Indeed, since a notch or a camera hole for camera exposure need not be formed in the display panel 110, the display device 100 can provide further advantages of reducing the size of a bezel area, and improving the degree of freedom in design because such limitations to the design are removed.

Although one or more optical electronic devices 11 are located on the back of (e.g., under, or in a lower portion of) the display panel 110 of the display device 100 (e.g., hidden or not to be exposed to the outside), the one or more optical electronic devices 11 are needed to perform normal predefined functionalities, and thus, receive or detect light.

Further, although one or more optical electronic devices 11 included in the display device 100 are located on the back of (e.g., under, or in a lower portion of) the display panel 110 to be hidden and located to be overlap with the display area DA, it is desirable for image display to be normally performed in the one or more optical areas (OA1) overlapping with the one or more optical electronic devices 11 in the display area DA. Thus, according to one or more aspects of the present disclosure, even though one or more optical electronic devices 11 are located on the back of the display panel, the display device 100 can present images in a normal manner (e.g., without reduction in image quality) in the one or more optical areas (OA1) of the display area DA overlapping with the one or more optical electronic devices 11.

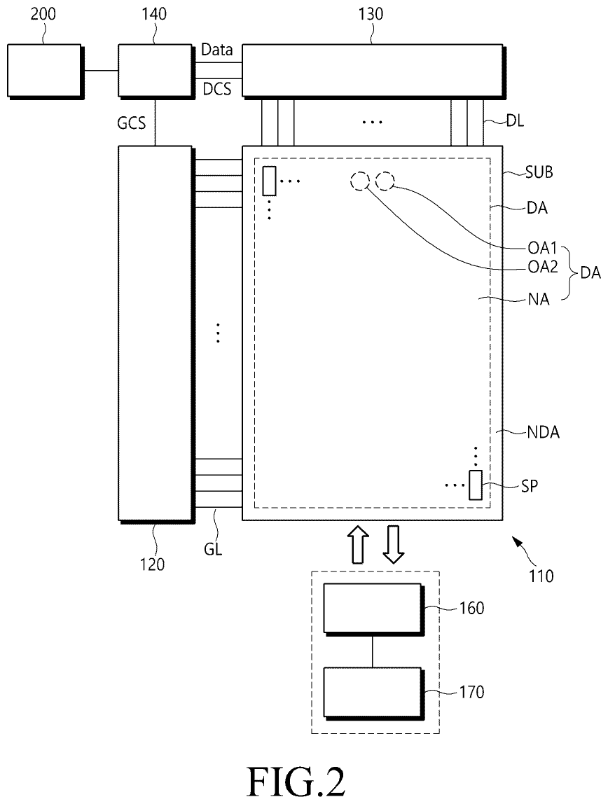

FIG. 2 illustrates an example system configuration of the display device 100 according to aspects of the present disclosure.

Referring to FIG. 2, in one or more example embodiments, the display device 100 can include the display panel 110 and at least one display driving circuit as components for displaying an image.

The at least one display driving circuit can be at least one circuit for driving the display panel 110. For example, the at least one display driving circuit can include a gate driving circuit 120, a data driving circuit 130, a display controller 140, and the like.

The display panel 110 can include a display area DA in which an image can be displayed and a non-display area NDA in which an image is not displayed. The non-display area NDA can be an area outside of the display area DA, and can also be referred to as a non-active area, a bezel area, or a bezel.

All or a portion of the non-display area NDA can be an area visible from the front surface of the display device 100, or an area not visible from the front surface of the display device 100 as a corresponding portion is bent.

The display panel 110 can include a substrate SUB and a plurality of subpixels SP disposed on the substrate SUB. The display panel 110 can further include several types of signal lines to drive the plurality of subpixels SP.

In one or more aspects, the display device 100 can be a liquid crystal display device, or a self-emission display device in which light is emitted from the display panel 110 itself. When the display device 100 according to one or more aspects is a self-emission display device, each of the plurality of subpixels SP can include a light emitting element.

For example, the display device 100 can be an organic light emitting display device in which the light emitting element is implemented with an organic light emitting diode (OLED). In another example, the display device 100 can be an inorganic light emitting display device in which the light emitting element is implemented with an inorganic material-based light emitting diode. In further another example, the display device 100 can be a quantum dot display device in which the light emitting element is implemented with quantum dots, which are self-emission semiconductor crystals.

Each, or one or more, of the plurality of subpixels SP included in the display device 100 can have a different structure depending on which type of the display device 100 is implemented. For example, when the display device 100 is a self-emission display device including self-emission subpixels SP, each subpixel SP can include a self-emission light emitting element, one or more transistors, and one or more capacitors.

In one or more aspects, signal lines disposed in the display device 100 can include a plurality of data lines DL for carrying data signals (which can be also referred to as data voltages or image signals), a plurality of gate lines GL for carrying gate signals (which can be also referred to as scan signals), and the like.

The plurality of data lines DL and the plurality of gate lines GL can intersect each other. Each of the plurality of data lines DL can be disposed to extend in a first direction. Each of the plurality of gate lines GL can be disposed to extend in a second direction.

For example, the first direction can be a column or vertical direction, and the second direction can be a row or horizontal direction. In another example, the first direction can be the row direction, and the second direction can be the column direction.

The data driving circuit 130 can be a circuit for driving the plurality of data lines DL, and can supply data signals to the plurality of data lines DL. The gate driving circuit 120 can be a circuit for driving the plurality of gate lines GL, and can supply gate signals to the plurality of gate lines GL.

The display controller 140 can be a device for controlling the data driving circuit 130 and the gate driving circuit 120, and can control driving timing for the plurality of data lines DL and driving timing for the plurality of gate lines GL.

The display controller 140 can supply a data driving control signal DCS to the data driving circuit 130 to control the data driving circuit 130, and supply a gate driving control signal GCS to the gate driving circuit 120 to control the gate driving circuit 120.

The display controller 140 can receive input image data from a host system 200 and supply image data Data based on the input image data to the data driving circuit 130.

The data driving circuit 130 can supply data signals to the plurality of data lines DL according to driving timing control of the display controller 140.

The data driving circuit 130 can receive the digital image data Data from the display controller 140, convert the received image data Data into analog data signals, and supply the resulting analog data signals to the plurality of data lines DL.

The gate driving circuit 120 can supply gate signals to the plurality of gate lines GL according to the timing control of the display controller 140. The gate driving circuit 120 can receive a first gate voltage corresponding to a turn-on level voltage and a second gate voltage corresponding to a turn-off level voltage along with various gate driving control signals GCS, generate gate signals, and supply the generated gate signals to the plurality of gate lines GL.

In one or more aspects, the data driving circuit 130 can be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique. However, aspects of the present disclosure are not limited thereto.

In one or more aspects, the gate driving circuit 120 can be connected to the display panel 110 by the tape-automated-bonding (TAB) technique, or connected to a conductive pad such as a bonding pad of the display panel 110 by the chip-on-glass (COG) technique or the chip-on-panel (COP) technique, or connected to the display panel 110 by the chip-on-film (COF) technique. However, aspects of the present disclosure are not limited thereto.

In one or more aspects, the gate driving circuit 120 can be disposed in the non-display area NDA of the display panel 110 by a gate-in-panel (GIP) technique. The gate driving circuit 120 can be disposed on a substrate, or connected to the substrate. For example, the gate driving circuit 120 implemented by the gate-in-panel (GIP) technique can be disposed in a portion of the non-display area NDA of the substrate. In one or more aspects, the gate driving circuit 120 can be connected to the substrate when the gate driving circuit 120 is implemented by the chip-on-glass (COG) technique, the chip-on-film (COF) technique, or the like.

In one or more aspects, at least one of the data driving circuit 130 and the gate driving circuit 120 can be disposed in the display area DA. For example, at least one of the data driving circuit 130 and the gate driving circuit 120 can be disposed not to overlap with subpixels SP, or be disposed to overlap with one or more, or all, of the subpixels SP.

The data driving circuit 130 can be located in, and/or electrically connected to, but not limited to, only one side or edge (e.g., an upper portion or a lower portion) of the display panel 110. In one or more aspects, the data driving circuit 130 can be disposed in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

The gate driving circuit 120 can be located in, and/or electrically connected to, but not limited to, only one side or edge (e.g., a left portion or a right portion) of the display panel 110. In one or more aspects, the gate driving circuit 120 can be disposed in, and/or electrically connected to, but not limited to, two sides or edges (e.g., a left portion and a right portion) of the display panel 110 or at least two of four sides or edges (e.g., the left portion, the right portion, an upper portion, and a lower portion) of the display panel 110 according to driving schemes, panel design schemes, or the like.

The display controller 140 can be implemented in a separate component from the data driving circuit 130, or integrated with the data driving circuit 130, so that the display controller 140 and the data driving circuit 130 can be implemented in a single integrated circuit.

The display controller 140 can be a timing controller used in the typical display technology or a control apparatus/device capable of additionally performing other control functionalities in addition to the typical function of the timing controller. In one or more embodiments, the display controller 140 can be one or more other control circuits different from the timing controller, or a circuit or component in the control apparatus/device. The display controller 140 can be implemented with various circuits or electronic components such as an integrated circuit (IC), a field programmable gate array (FPGA), an application specific integrated circuit (ASIC), a processor, and/or the like.

The display controller 140 can be mounted on a printed circuit board, a flexible printed circuit, or the like, and can be electrically connected to the data driving circuit 130 and the gate driving circuit 120 through the printed circuit board, the flexible printed circuit, and/or the like.

The display controller 140 can transmit signals to, and receive signals from, the data driving circuit 130 via one or more predetermined interfaces. For example, such interfaces can include a low voltage differential signaling (LVDS) interface, an embedded clock point-point interface (EPI), a serial peripheral interface (SPI), and the like.

In one or more example embodiments, to further provide a touch sensing function, as well as an image display function, the display device 100 can include at least one touch sensor, and a touch circuit configured to detect whether a touch event occurs, which is caused by a touch object such as a finger, a pen, or the like, or to detect a corresponding touch position, by sensing the touch sensor. It should be noted herein that a touch sensor can be referred to as all, or one or more, of a plurality of touch electrodes included in the display panel 110 according to design requirements.

The touch circuit can include a touch driving circuit 160 configured to generate and provide touch sensing data by driving and sensing the touch sensor, a touch controller 170 configured to detect the occurrence of the touch event or detect the touch position using the touch sensing data, and one or more other components.

In one or more aspects, the touch sensor can include a plurality of touch electrodes. The touch sensor can further include a plurality of touch lines for electrically connecting the plurality of touch electrodes to the touch driving circuit 160.

The touch sensor can be added to the outside of the display panel 110 in the form of a touch panel, or be integrated to the inside of the display panel 110. The touch sensor added to the outside of the display panel 110 in the form of the touch panel can be referred to as an add-on type of touch sensor. In the example where the add-on type of touch sensor is employed, a corresponding touch panel and the display panel 110 can be separately manufactured and coupled during an assembly process. The add-on type of touch panel can include a touch panel substrate and a plurality of touch electrodes on the touch panel substrate.

In the example where the touch sensor is integrated to the inside of the display panel 110, the touch sensor can be formed over the substrate SUB together with signal lines and electrodes related to driving the display device 100 during the process of manufacturing the display panel 110.

The touch driving circuit 160 can supply a touch driving signal to at least one of a plurality of touch electrodes, sense at least one of the plurality of touch electrodes, and generate touch sensing data based on a result from the sensing.

The touch circuit can perform touch sensing by a self-capacitance sensing technique or a mutual-capacitance sensing technique.

In the example where the touch circuit performs touch sensing by the self-capacitance sensing technique, the touch circuit can perform touch sensing based on capacitance between each touch electrode and a touch object (e.g., a finger, a pen, and the like).

According to the self-capacitance sensing technique, each of the plurality of touch electrodes can serve as both a driving touch electrode and a sensing touch electrode. The touch driving circuit 160 can drive all, or one or more, of the plurality of touch electrodes and sense all, or one or more, of the plurality of touch electrodes.

In the example where the touch circuit performs touch sensing by the mutual-capacitance sensing technique, the touch circuit can perform touch sensing based on capacitance between touch electrodes.

According to the mutual-capacitance sensing technique, the plurality of touch electrodes can be divided into one or more driving touch electrodes and one or more sensing touch electrodes. The touch driving circuit 160 can drive the driving touch electrodes and sense the sensing touch electrodes.

In one or more aspects, the touch driving circuit 160 and the touch controller 170 included in the touch circuit can be implemented in separate devices or be integrated into a single device. In one or more aspects, the touch driving circuit 160 and the data driving circuit 130 can be implemented in separate devices, or be integrated into a single device.

The display device 100 can further include a power supply circuit configured to supply several types of power to the display driving circuit and/or the touch circuit.

In one or more aspects, the display device 100 can be a mobile terminal such as a smart phone, a tablet, or the like, or a monitor, a television (TV), or the like. Such apparatuses can be configured in various types, sizes, and shapes. The display device 100 according to aspects of the present disclosure are not limited thereto, and can include various types, sizes, and shapes configured to display information or images, a display apparatus according to the aspects of the present disclosure can be applied to mobile devices, video phones, smart watches, watch phones, wearable apparatuses, foldable apparatuses, rollable apparatuses, bendable apparatuses, flexible apparatuses, stretchable apparatuses, curved apparatuses, sliding apparatuses, variable apparatuses, electronic notebooks, e-books, portable multimedia players (PMP), personal digital assistants (PDA), MP3 players, mobile medical apparatuses, desktop PCs, laptop PCs, netbook computers, workstations, navigation apparatuses, car navigation apparatuses, vehicle display apparatuses, vehicle apparatuses, theater apparatuses, theater display apparatuses, televisions, wallpaper apparatuses, signage apparatuses, game apparatuses, notebook computers, monitors, cameras, camcorders, and home appliances, and the like.

As described above with reference to FIG. 1, the display area DA of the display panel 110 can include the normal area NA and the one or more optical areas (OA1 and/or OA2).

The normal area NA and the one or more optical areas (OA1 and/or OA2) can be areas where images can be displayed. It should be noted here that the normal area NA can be an area in which a light transmission structure need not be implemented, and the one or more optical areas (OA1 and/or OA2) can be areas in which a light transmission structure need be implemented.

As discussed above with reference to FIG. 1, even though the display area DA of the display panel 110 can include the one or more optical areas (OA1 and/or OA2) together with the normal area NA, for convenience of description, discussions that follow will be provided based on examples where the display area DA includes both first and second optical areas (OA1 and OA2).

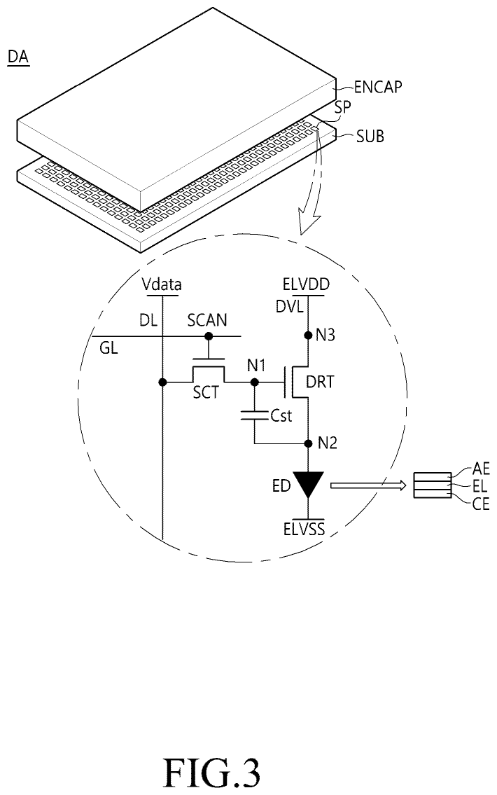

FIG. 3 illustrates an example equivalent circuit of each, or one or more, of subpixels included in a display panel 110 according to aspects of the present disclosure.

Referring to FIG. 3, in one or more example embodiments, each of subpixels SP disposed in the normal area NA, the first optical area OA1, and the second optical area OA2 included in the display area DA of the display panel 110 can include a light emitting element ED, a driving transistor DRT for driving the light emitting element ED, a scan transistor SCT for allowing a data voltage Vdata to be applied to a first node N1 of the driving transistor DRT, a storage capacitor Cst for maintaining a voltage at an approximate constant level during one frame or one or more of periods including in one frame, and the like.

The driving transistor DRT can include the first node N1 to which a data voltage Vdata is applied, a second node N2 electrically connected to the light emitting element ED, and a third node N3 to which a driving voltage ELVDD through a driving voltage line DVL is applied. In the driving transistor DRT, the first node N1 can be a gate node, the second node N2 can be a source node or a drain node, and the third node N3 can be the drain node or the source node.

The light emitting element ED can include an anode electrode AE, an emission layer EL, and a cathode electrode CE. The anode electrode AE can be a pixel electrode disposed in each subpixel SP, and be electrically connected to the second node N2 of the driving transistor DRT of each subpixel SP. The cathode electrode CE can be a common electrode commonly disposed in a plurality of subpixels SP, and a base voltage ELVSS such as a low level of voltage can be applied to the cathode electrode CE.

For example, the anode electrode AE can be a pixel electrode, and the cathode electrode CE can be a common electrode. In another example, the anode electrode AE can be a common electrode, and the cathode electrode CE can be a pixel electrode. For convenience of description, discussions that follow will be provided based on examples where the anode electrode AE is a pixel electrode, and the cathode electrode CE is a common electrode unless explicitly stated otherwise. However, it should be understood that the scope of the present disclosure includes examples where the anode electrode AE is a common electrode, and the cathode electrode CE is a pixel electrode.

The light emitting element ED can be, for example, an organic light emitting diode (OLED), an inorganic light emitting diode (LED), a quantum dot (QD) light emitting element, a micro light emitting diode, a mini light emitting diode, or the like, but aspects of the present disclosure are not limited thereto. In the example where an organic light emitting diode (OLED) is used as the light emitting element ED, the emission layer EL included in the light emitting element ED can include an organic emission layer including an organic material.

The scan transistor SCT can be turned on and off by a scan signal SCAN, which is a gate signal applied through a gate line GL, and be electrically connected between the first node N1 of the driving transistor DRT and a data line DL.

The storage capacitor Cst can be electrically connected between the first node N1 and the second node N2 of the driving transistor DRT.

Each subpixel SP can include two transistors (2T: DRT and SCT) and one capacitor (1C: Cst) (which can be referred to as a “2T1C structure”) as shown in FIG. 3. In some implementations, each subpixel SP can further include one or more transistors, or further include one or more capacitors.

In one or more aspects, the storage capacitor Cst can be an external capacitor intentionally configured or designed to be located outside of the driving transistor DRT, other than internal capacitors such as parasitic capacitors (e.g., a gate-to-source capacitance Cgs, a gate-to-drain capacitance Cgd, and the like) that can be present between the first node N1 and the second node N2 of the driving transistor DRT.

Each of the driving transistor DRT and the scan transistor SCT can be an n-type transistor or a p-type transistor.

Since some circuit elements (in particular, a light emitting element ED) in each subpixel SP can be easily damaged by external moisture or oxygen, an encapsulation layer ENCAP can be disposed in the display panel 110 to prevent the external moisture or oxygen from penetrating into such circuit elements (in particular, the light emitting element ED). The encapsulation layer ENCAP can be disposed such that it covers the light emitting element ED.

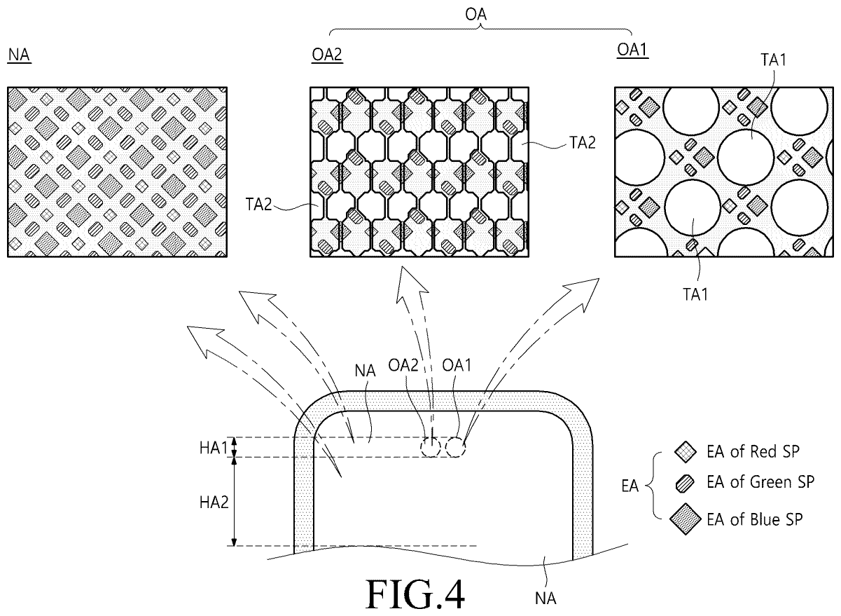

FIG. 4 illustrates example subpixel arrangements in three areas included in the display area DA of the display panel 110 according to aspects of the present disclosure.

Referring to FIG. 4, in one or more example embodiments, a plurality of subpixels SP can be disposed in each of the normal area NA, the first optical area OA1, and the second optical area OA2 included in the display area DA of the display panel 110.

The plurality of subpixels SP can include, for example, at least one red subpixel (Red SP) emitting red light, at least one green subpixel (Green SP) emitting green light, and at least one blue subpixel (Blue SP) emitting blue light.

Accordingly, each of the normal area NA, the first optical area OA1, and the second optical area OA2 can include one or more light emitting areas EA of one or more red subpixels (Red SP), one or more light emitting areas EA of one or more green subpixels (Green SP), and one or more light emitting areas EA of one or more blue subpixels (Blue SP).

It should be understood here that the normal area NA may not include a light transmission structure, but include light emitting areas EA.

In contrast, it is desirable that the first optical area OA1 and the second optical area OA2 include both light emitting areas EA and such a light transmission structure.

Accordingly, in one or more aspects, the first optical area OA1 can include one or more light emitting areas EA and one or more first transmission areas TA1, and the second optical area OA2 can include one or more light emitting areas EA and one or more second transmission areas TA2.

In one or more aspects, the light emitting areas EA and the transmission areas (TA1 and/or TA2) can be distinct according to whether the transmission of light is allowed. For example, the light emitting areas EA can be areas not allowing light to be transmitted, and the transmission areas (TA1 and/or TA2) can be areas allowing light to be transmitted (e.g., allowing light to travel through a lower portion or lower surface of the display panel 110).

In one or more aspects, the light emitting areas EA and the transmission areas (TA1 and/or TA2) can be also distinct according to whether or not a specific metal layer is included. For example, a cathode electrode CE (e.g., the cathode electrode CE illustrated in FIG. 3) can be disposed in the light emitting areas EA, and a cathode electrode CE may not be disposed in the transmission areas (TA1 and/or TA2). In one or more aspects, a light shield layer can be disposed in the light emitting areas EA, and a light shield layer may not be disposed in the transmission areas (TA1 and/or TA2).

Since the first optical area OA1 includes the first transmission areas TA1 and the second optical area OA2 includes the second transmission areas TA2, both of the first optical area OA1 and the second optical area OA2 can be areas through which light can be transmitted.

In one or more aspects, a transmittance (a degree of transmission) of the first optical area OA1 and a transmittance (a degree of transmission) of the second optical area OA2 can be substantially the same as each other.

For example, each, or one or more, of the first transmission areas TA1 of the first optical area OA1 and each, or one or more, of the second transmission areas TA2 of the second optical area OA2 can have substantially the same shape or size as each other. In another example, even when each, or one or more, of the first transmission areas TA1 of the first optical area OA1 and each, or one or more, of the second transmission areas TA2 of the second optical area OA2 have different shapes or sizes, a ratio of each, or one or more, of the first transmission areas TA1 to the first optical area OA1 and a ratio of each, or one or more, of the second transmission areas TA2 to the second optical area OA2 can be substantially the same as each other.

In one or more aspects, a transmittance (a degree of transmission) of the first optical area OA1 and a transmittance (a degree of transmission) of the second optical area OA2 can be different from each other.

For example, each, or one or more, of the first transmission areas TA1 of the first optical area OA1 and each, or one or more, of the second transmission areas TA2 of the second optical area OA2 can have different shapes or sizes from each other. In another example, even when each, or one or more, of the first transmission areas TA1 of the first optical area OA1 and each, or one or more, of the second transmission areas TA2 of the second optical area OA2 have substantially the same shape or size, a ratio of each, or one or more, of the first transmission areas TA1 to the first optical area OA1 and a ratio of each, or one or more, of the second transmission areas TA2 to the second optical area OA2 can be different from each other.

For example, in the example where an optical electronic device overlapping with the first optical area OA1 is a camera, and an optical electronic device overlapping with the second optical area OA2 is a sensor for detecting images, the camera can need a greater amount of light than the sensor.

According to this configuration, the transmittance (degree of transmission) of the first optical area OA1 can be greater than the transmittance (degree of transmission) of the second optical area OA2.

For example, each, or one or more, of the first transmission areas TA1 of the first optical area OA1 can have a size greater than each, or one or more, of the second transmission areas TA2 of the second optical area OA2. In another example, even when each, or one or more, of the first transmission areas TA1 of the first optical area OA1 and each, or one or more, of the second transmission areas TA2 of the second optical area OA2 have substantially the same size, a ratio of each, or one or more, of the first transmission areas TA1 to the first optical area OA1 can be greater than a ratio of each, or one or more, of the second transmission areas TA2 to the second optical area OA2.

For convenience of description, discussions that follow are provided based on an example in which the transmittance (degree of transmission) of the first optical area OA1 is greater than the transmittance (degree of transmission) of the second optical area OA2.

The transmission areas (TA1, TA2) can be referred to as transparent areas and the term transmittance can be referred to as transparency.

Further, in discussions that follow, it is assumed that the first optical areas OA1 and the second optical areas OA2 are located in an upper edge of the display area DA of the display panel 110, and are disposed to be horizontally adjacent to each other in a direction in which the upper edge extends unless explicitly stated otherwise.

A horizontal display area in which the first optical area OA1 and the second optical area OA2 are disposed can be referred to as a first horizontal display area HA1, and another horizontal display area in which the first optical area OA1 and the second optical area OA2 are not disposed can be referred to as a second horizontal display area HA2.

The first horizontal display area HA1 can include the normal area NA, the first optical area OA1, and the second optical area OA2. The second horizontal display area HA2 can include only the normal area NA.

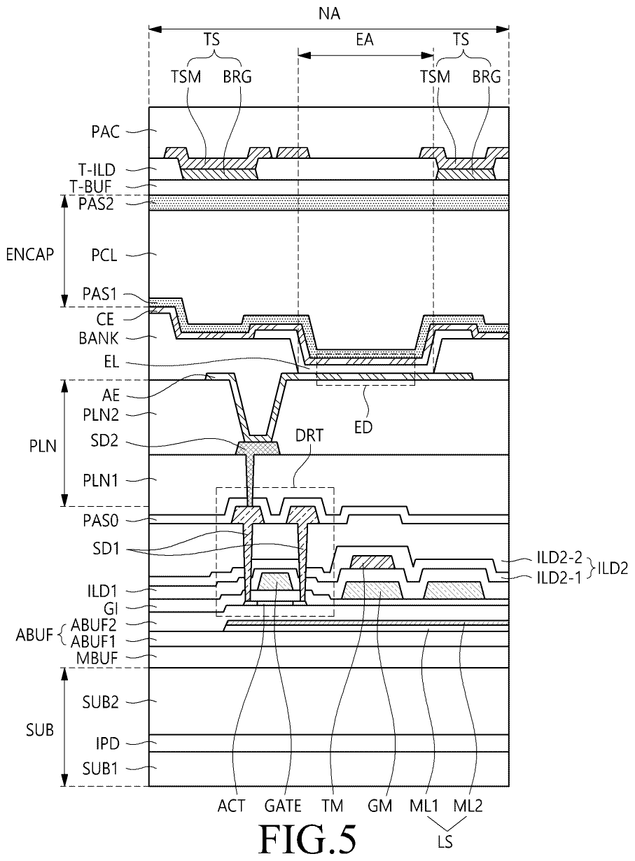

FIG. 5 is an example cross-sectional view of a portion of the display area DA in the display panel 110 according to aspects of the present disclosure.

Particularly, FIG. 5 illustrates a portion of the normal area NA except for an optical areas OA where an optical electronic device 11 is located.

Referring to FIG. 5, in one or more example embodiments, the display panel 110 of the display device 100 can include a substrate SUB, a driving transistor DRT, a planarization layer PLN, a light emitting element ED, an encapsulation layer ENCAP, and a touch layer.

The substrate SUB can include a first substrate SUB1, a substrate insulating layer IPD, and a second substrate SUB2. The substrate insulating layer IPD can be interposed between the first substrate SUB1 and the second substrate SUB2.

As the substrate SUB includes the first substrate SUB1, the substrate insulating layer IPD, and the second substrate SUB2, the substrate SUB can prevent or reduce the penetration of moisture.

The first substrate SUB1 and the second substrate SUB2 can be, for example, polyimide (PI) substrates. The first substrate SUB1 can be referred to as a primary PI substrate, and the second substrate SUB2 can be referred to as a secondary PI substrate.

Several types of patterns (ACT, SD1, and/or GATE) for forming one or more transistors such as the driving transistor DRT, and the like, several types of insulating layers (MBUF, ABUF1, ABUF2, GI, ILD1, ILD2, and/or PAS0), and several types of metal patterns (TM, GM, ML1, and/or ML2) can be disposed on or over the substrate SUB.

For example, a multi-buffer layer MBUF can be disposed on the second substrate SUB2, and a first active buffer layer ABUF1 can be disposed on the multi-buffer layer MBUF.

A first metal layer ML1 and a second metal layer ML2 can be disposed on the first active buffer layer ABUF1. For example, the first metal layer ML1 and the second metal layer ML2 can be light shield layers LS for shielding light.

A second active buffer layer ABUF2 can be disposed on the first metal layer ML1 and the second metal layer ML2. An active layer ACT of the driving transistor DRT can be disposed on the second active buffer layer ABUF2.

A gate insulating layer GI can be disposed such that it covers the active layer ACT.

A gate electrode GATE of the driving transistor DRT can be disposed on the gate insulating layer GI. Further, a gate material layer GM can be disposed on the gate insulating layer GI, together with the gate electrode GATE of the driving transistor DRT, at a location different from the location where the driving transistor DRT is disposed.

A first interlayer insulating layer ILD1 can be disposed such that it covers the gate electrode GATE and the gate material layer GM. A metal pattern TM can be disposed on the first interlayer insulating layer ILD1. The metal pattern TM can be disposed at a location different from the location where the driving transistor DRT is disposed.

A second interlayer insulating layer ILD2 can be disposed such that it covers the metal pattern TM on the first interlayer insulating layer ILD1.

Two first source-drain electrode patterns SD1 can be disposed on the second interlayer insulating layer ILD2. One of the two first source-drain electrode patterns SD1 can be a source node of the driving transistor DRT, and the other can be a drain node of the driving transistor DRT.

The two first source-drain electrode patterns SD1 can be electrically connected to first and second side portions of the active layer ACT, respectively, through contact holes formed in the second interlayer insulating layer ILD2, the first interlayer insulating layer ILD1, and the gate insulating layer GI.

In one or more aspects, the second interlayer insulating layer ILD2 can include a second-first interlayer insulating layer ILD2-1 and a second-second interlayer insulating layer ILD2-2. The second-first interlayer insulating layer ILD2-1 can be located such that it covers the metal pattern TM. The second-second interlayer insulating layer ILD2-2 can be located on the second-first interlayer insulating layer ILD2-1.

A portion overlapping with the gate electrode GATE among portions of the active layer ACT can serve as a channel region. One of the two first source-drain electrode patterns SD1 can be connected to the first side portion of the channel region of the active layer ACT, and the other of the two first source-drain electrode patterns SD1 can be connected to the second side portion of the channel region of the active layer ACT.

A passivation layer PAS0 can be disposed such that it covers the two first source-drain electrode patterns SD1. The planarization layer PLN can be disposed on the passivation layer PAS0.

The planarization layer PLN can include a first planarization layer PLN1 and a second planarization layer PLN2.

The first planarization layer PLN1 can be disposed on the passivation layer PAS0.

A second source-drain electrode pattern SD2 can be disposed on the first planarization layer PLN1. The second source-drain electrode pattern SD2 can be connected to one of the two first source-drain electrode patterns SD1 (corresponding to the second node N2 of the driving transistor DRT in the subpixel SP of FIG. 3) through a contact hole formed in the first planarization layer PLN1.

The second planarization layer PLN2 can be disposed such that it covers the second source-drain electrode pattern SD2. The light emitting element ED can be disposed on the second planarization layer PLN2.

The light emitting element ED can include an anode electrode AE, an emission layer EL, and a cathode electrode CE.

The anode electrode AE can be disposed on the second planarization layer PLN2. The anode electrode AE can be electrically connected to the second source-drain electrode pattern SD2 through a contact hole formed in the second planarization layer PLN2.

A bank BANK can be disposed such that it covers a portion of the anode electrode AE. A portion of the bank BANK corresponding to a light emitting area EA of the light emitting element ED can be opened.

A portion of the anode electrode AE can be exposed through the opening (the opened portion) of the bank BANK.

The emission layer EL can be disposed on one or more side surfaces of the bank BANK and in the opening (the opened portion) of the bank BANK. All or at least part of the emission layer EL can be located between adjacent banks. The emission layer EL can include an organic material film.

In the opening of the bank BANK, the emission layer EL can contact the anode electrode AE. The cathode electrode CE can be disposed on the emission layer EL.

The encapsulation layer ENCAP can be disposed on the light emitting element ED.

The encapsulation layer ENCAP can have a single-layer stack or a multi-layer stack. For example, the encapsulation layer ENCAP can include a first encapsulation layer PAS1, a second encapsulation layer PCL, and a third encapsulation layer PAS2.

For example, the first encapsulation layer PAS1 and the third encapsulation layer PAS2 can be inorganic layers, and the second encapsulation layer PCL can be an organic layer. Among the first encapsulation layer PAS1, the second encapsulation layer PCL, and the third encapsulation layer PAS2, the second encapsulation layer PCL can have the greatest thickness. According to this implementation, the second encapsulating layer PCL can serve as a planarization layer.

The first encapsulating layer PAS1 can also be referred to as a first inorganic encapsulating layer, the second encapsulating layer PCL can also be referred to as an organic encapsulating layer, and the third encapsulating layer PAS2 can also be referred to as a second inorganic encapsulating layer.

The first encapsulation layer PAS1 can be disposed on the cathode electrode CE and be disposed closest to the stack of the light emitting element ED. The first encapsulation layer PAS1 can include an inorganic insulating material capable of being deposited by low-temperature deposition. For example, the first encapsulation layer PAS1 can include, but not limited to, silicon nitride (SiNx), silicon oxide (SiOx), silicon oxynitride (SiON), aluminum oxide (Al2O3), or the like. Since the first encapsulation layer PAS1 can be deposited in a low temperature atmosphere during the deposition process, the first encapsulation layer PAS1 can prevent the emission layer EL including an organic material vulnerable to a high temperature atmosphere from being damaged.

The second encapsulation layer PCL can have a smaller area or size than the first encapsulation layer PAS1. For example, the second encapsulation layer PCL can be disposed such that it exposes both ends or edges of the first encapsulation layer PAS1. The second encapsulation layer PCL can serve as a buffer for relieving stress between corresponding layers while the display device 100 is curved or bent, and also serve to enhance planarization performance.

For example, the second encapsulation layer PCL can include an organic insulating material, such as acrylic resin, epoxy resin, polyimide, polyethylene, silicon oxycarbon (SiOC), or the like. The second encapsulation layer PCL can be disposed, for example, by an inkjet technique.

The third encapsulation layer PAS2 can be disposed on the second encapsulation layer PCL such that the third encapsulation layer PAS2 covers the respective top surfaces and side surfaces of the second encapsulation layer PCL and the first encapsulation layer PAS1. The third encapsulation layer PAS2 can minimize or prevent external moisture or oxygen from penetrating into the first encapsulation layer PAS1 and the second encapsulation layer PCL.

For example, the third encapsulation layer PAS2 can include an inorganic insulating material, such as silicon nitride (SiNx), silicon oxide (SiOx), silicon oxynitride (SiON), aluminum oxide (Al2O3), or the like.

In one or more aspects, the display device 100 can include a touch sensor TS disposed on the encapsulation layer ENCAP to detect a touch by a user's finger or pen.

In an example where the touch sensor TS is embedded into the display panel 110, the touch sensor TS can be disposed on the encapsulation layer ENCAP. The structure of the touch sensor will be described in detail as follows.

A touch buffer layer T-BUF can be disposed on the encapsulation layer ENCAP.

The touch sensor TS can be disposed on the touch buffer layer T-BUF.

The touch sensor TS can include touch sensor metals TSM and at least one bridge metal BRG, which are located in different layers from each other.

In one or more aspects, each touch sensor metal TSM and each bridge metal BRG can have a stack of three layers, for example, configured with Ti, Al, and Ti.

A touch interlayer insulating layer T-ILD can be disposed between the touch sensor metals TSM and the at least one bridge metal BRG.

The touch interlayer insulating layer T-ILD can include an inorganic material such as silicon nitride SiNx or an organic material such as silicon oxide SiOx. In one or more aspects, the touch interlayer insulating layer T-ILD can be formed using an organic material of silicon oxide SiOx to improve touch performance.

For example, the touch sensor metal TSM can include a first touch sensor metal, a second touch sensor metal, and a third touch sensor metal, which are disposed adjacent to one another.

In an implementation where the third touch sensor metal is disposed between the first touch sensor metal and the second touch sensor metal, and the first touch sensor metal and the second touch sensor metal are needed to be electrically connected to each other, the first touch sensor metal and the second touch sensor metal can be electrically connected to each other through a bridge metal BRG disposed in another layer.

The bridge metal BRG can be electrically insulated from the third touch sensor metal by the touch interlayer insulating layer T-ILD.

During the process of forming the touch sensor TS on the display panel 110, a chemical solution (e.g., a developer, etchant, or the like) used in this process can be generated or moisture from the outside can be introduced.

In one or more aspects, by disposing the touch sensor TS on the touch buffer layer T-BUF, a chemical solution or moisture can be prevented from penetrating into the emission layer EL including an organic material during the process of manufacturing the touch sensor TS.

By applying this implementation, the touch buffer layer T-BUF can prevent the emission layer EL from being damaged by a chemical solution or moisture.

To prevent the emission layer EL including an organic material, which is vulnerable to high temperatures, from being damaged, the touch buffer layer T-BUF can be formed at a low temperature less than or equal to a predefined temperature (e.g., about 100 degree Celsius) and include an organic insulating material with a low dielectric constant. For example, the touch buffer layer T-BUF can include an acrylic-based, epoxy-based, or siloxan-based material.

In an example where the display device 100 is a bendable or foldable display device, as the display device 100 is bent or folded, the encapsulation layer ENCAP can be damaged, and the touch sensor metals TSM located on the touch buffer layer T-BUF can be cracked or broken. Even when the display device 100 is bent or folded, the touch buffer layer T-BUF including an organic insulating material and having a planarization performance can prevent the encapsulation layer ENCAP from being damaged or prevent the touch sensor metals TSM or the at least one bridge metal BRG from being cracked or broken.

A protective layer PAC can be disposed such that it covers the touch sensor TS. The protective layer PAC can be, for example, an organic insulating layer.

In an example where this display panel 110 includes a through hole TH for an optical electronic device, moisture can penetrate the through hole TH, and reach one or more adjacent emission layers EL. In this situation, one or more light emitting elements ED disposed adjacent to the through hole TH can be damaged by such moisture.

In addition, moisture generated during the process of forming the touch sensor TS or coming from the outside can enter the encapsulation layer ENCAP through the touch interlayer insulating layer T-ILD and touch buffer layer T-BUF, which are disposed on the encapsulation layer ENCAP, and damage the light emitting element ED.

In one or more aspects, the display panel 110 can provide an advantage of blocking moisture from penetrating such a through hole TH by forming an emission layer cutting pattern by which an emission layer EL between the through hole TH and the normal area NA is cut up.

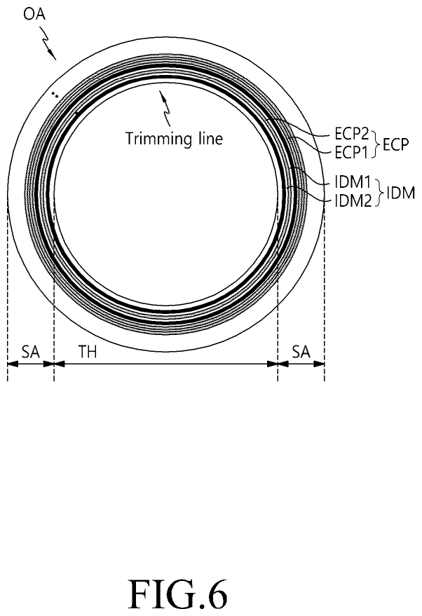

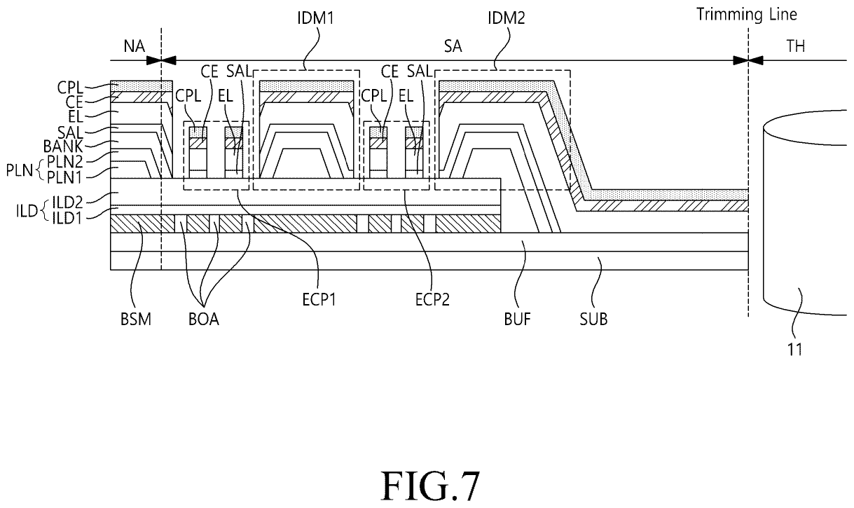

FIG. 6 is an example plan view of an optical area in the display panel 110 according to aspects of the present disclosure. FIG. 7 is an example cross-sectional view of the optical area in the display panel 110 according to aspects of the present disclosure.

Referring to FIGS. 6 and 7, in one or more example embodiments, the display panel 110 can include at least one optical area OA disposed in the display area DA.

For example, a plurality of subpixels can be disposed in the at least one optical area OA. In another example, subpixels for displaying an image may not be disposed in the at least one optical area OA.

The at least one optical area OA can be the first optical area OA1 or the second optical area OA2 described above.

The at least one optical area OA can include a through hole TH and a surrounding area SA outside of the through hole TH.

At least one emission layer cutting pattern ECP for preventing the penetration of moisture can be disposed in the surrounding area SA.

The through hole TH can be formed by removing a portion of the substrate SUB along a trimming line. The shape of the through hole TH can be circular, but aspects of the present disclosure are not limited thereto. For example, the shape of the through hole TH can have various shapes such as an oval, a square, a hexagon, or an octagon.

To block moisture passing through a path along an emission layer EL, the at least one emission layer cutting pattern ECP can include a first emission layer cutting pattern ECP1 and a second emission layer cutting pattern ECP2.

The first emission layer cutting pattern ECP1 can be disposed at a location close to the normal area NA, and the second emission layer cutting pattern ECP2 can be disposed at a location close to the through hole TH.

At least one inner dam IDM can be disposed around the first emission layer cutting pattern ECP1 and the second emission layer cutting pattern ECP2 to allow the first emission layer cutting pattern ECP1 and the second emission layer cutting pattern ECP2 to be spaced apart from each other.

For example, a first inner dam IDM1 can be disposed between the first emission layer cutting pattern ECP1 and the second emission layer cutting pattern ECP2, and a second inner dam IDM2 can be disposed between the second emission layer cutting pattern ECP2 and the through hole TH.

In one or more aspects, an outer dam can be further located in a portion of the normal area NA outside of the first emission layer cutting pattern ECP1. The outer dam can be disposed to prevent an encapsulation layer ENCAP (e.g., the encapsulation layer ENCAP discussed above with reference to FIGS. 3 and 5) from overflowing toward the outside of the normal area NA.

The inner dams IDM can have a shape corresponding to the shape of the through hole TH. For example, the inner dams IDM can have a closed curve shape surrounding the through hole TH. The inner dams IDM and the through hole TH can have different closed curve shapes, or have closed curve shapes with the same shape but different sizes. For example, the inner dams IDM and the through hole TH can have concentric shapes and be disposed to be spaced apart from each other by a certain interval.

The emission layer cutting patterns ECP can have a closed curve shape corresponding to the shape of the through hole TH and surrounding the through hole TH. The emission layer cutting patterns ECP and the through hole TH can have different closed curve shapes, or have closed curve shapes with the same shape but different sizes.

FIG. 6 illustrates an example where the emission layer cutting patterns ECP and the through hole TH have the same shape and are spaced apart from each other by a certain interval, but aspects of the present disclosure are not limited thereto.

In one or more aspects, each of subpixels disposed in the normal area NA can include a light emitting element ED. In an example where this light emitting element ED is an organic light emitting element, an emission layer EL can be disposed in the normal area NA, and the emission layer EL can be an organic emission layer including an organic material.

In this implementation, the emission layer EL can be disposed from the normal area NA to at least a part of the optical area OA.

In one or more aspects, a capping layer CPL can be disposed on the light emitting element ED to improve light extraction and protect the light emitting element ED. The capping layer CPL can include an organic material having a low molecular structure. In one or more aspects, the capping layer CPL can be omitted.

The optical area OA can include the through hole TH and the surrounding area SA, and the normal area NA can be located outside of the surrounding area SA.

An optical electronic device 11 can be disposed in the through hole TH such that the optical electronic device 11 is located under, or at a lower portion of, the display panel 110 and at least partially overlaps with the through hole TH.

The first emission layer cutting pattern ECP1 can be disposed between the normal area NA and the first inner dam IDM1, and the second emission layer cutting pattern ECP2 can be disposed between the first inner dam IDM1 and the second inner dam IDM2. In one or more aspects, the second inner dam IDM2 between the first inner dam IDM1 and the through hole TH can be omitted.

The at least one emission layer cutting pattern ECP (i.e., ECP1 and/or ECP2) can include a ridge protruding upwardly and a valley from which the emission layer EL is removed.

The emission layer EL can be included in at least a portion of the at least one emission layer cutting pattern ECP. The emission layer EL can be an organic emission layer EL including an organic material.

For example, the ridge of the at least one emission layer cutting pattern ECP can have a structure in which a sacrificial layer SAL, the emission layer EL, a cathode electrode CE, and the capping layer CPL are sequentially stacked.

The sacrificial layer SAL can be formed together while light emitting elements ED of the normal area NA are formed. The sacrificial layer SAL can be located on a bank BANK.

For example, the sacrificial layer SAL can be disposed only in an area where the second emission layer cutting pattern ECP2 is located between the first inner dam IDM1 and the second inner dam IDM2. In another example, the sacrificial layer SAL can be disposed in both areas where the inner dams (IDM1 and IDM2) are located and an area where the at least one emission layer cutting pattern ECP is located. FIG. 7 illustrates an example where the sacrificial layer SAL is disposed both areas where the inner dams (IDM1 and IDM2) are located and areas where the emission layer cutting patterns (ECP1 and ECP2) are located, but aspects of the present disclosure are not limited thereto.

The sacrificial layer SAL can include a conductive oxide, a metal, or a metal compound. The sacrificial layer SAL can further include a film of ITO, IZO, ZnO, In2O3 disposed on top and bottom of a metal reflective film. For example, the sacrificial layer SAL can have a structure in which ITO, Ag, and ITO are stacked.

At this implementation, a shielding layer BSM can be disposed under the at least one emission layer cutting pattern ECP such that the shielding layer BSM corresponds to the structure of the at least one emission layer cutting pattern ECP.

The shielding layer BSM can be disposed between the at least one emission layer cutting pattern ECP and the substrate SUB. For example, the shielding layer BSM can be disposed on a buffer layer BUF.

The shielding layer BSM can be disposed at a location corresponding to a corresponding ridge of the at least one emission layer cutting pattern ECP, and the shielding layer BSM can be opened at a location corresponding to a corresponding valley of the at least one emission layer cutting pattern ECP.

These configurations can be implemented such that among laser beams that are incident to the shielding layer BSM, some laser beams passing through at least one open area BOA of the shielding layer BSM remove respective portions of the sacrificial layer SAL, the emission layer EL, the cathode electrode CE, and the capping layer CPL corresponding to at least one open area BOA of the shielding layer BSM, and thereby, a corresponding valley of the at least one emission layer cutting pattern ECP is formed.

According to this implementation, the at least one open area BOA of the shielding layer BSM can block some laser beams corresponding to a low energy area in energy released from the laser beams, and thereby, the display panel 110 can provide an advantage of preventing the cathode electrode CE located over the shielding layer BSM from being burred (e.g., an edge of the cathode electrode CE is raised) due to the low energy area.

The emission layer EL can extend from the normal area NA to at least a part of the surrounding area SA. According to the configurations discussed above, the emission layer EL can be discontinuously disposed in the first emission layer cutting pattern ECP1 and the second emission layer cutting pattern ECP2.

According to this implementation, even if moisture penetrating the through hole TH enters the emission layer EL located in the surrounding area SA, the moisture can be prevented from reaching the emission layer EL located in the normal area NA. Thus, as the emission layer EL is disposed discontinuously in the at least one emission layer cutting pattern ECP, the display panel 110 can provide an effect or advantage of causing a moisture permeation path to be lengthened, and preventing moisture entering the emission layer EL from reaching the normal area NA.

In one or more aspects, heights of respective ridges in the first emission layer cutting pattern ECP1 and the second emission layer cutting pattern ECP2 can be different from each other. The height of the ridge in the first emission layer cutting pattern ECP1 can be greater than that of the ridge in the second emission layer cutting pattern ECP2.

The reason why the heights of the ridges in the first emission layer cutting pattern ECP1 and the second emission layer cutting pattern ECP2 are different can be due to the fact that respective interlayer insulating layers ILD included in the ridges in the first emission layer cutting pattern ECP1 and the second emission layer cutting pattern ECP2 are different.

In one or more aspects, the bottom surface of a valley located in the second emission layer cutting pattern ECP2 can be located lower than the bottom surface of a valley located in the first emission layer cutting pattern ECP1.

According to this configuration, as the display panel 110 includes the shielding layer BSM located over the substrate SUB and having a structure corresponding to the at least one emission layer cutting pattern ECP, the display panel 110 can provide an advantage of preventing or reducing a bur phenomenon in which an edge of a metal layer (e.g., the cathode electrode CE discussed above) is raised due to a difference in energy intensities during the process of forming the at least one emission layer cutting pattern ECP.

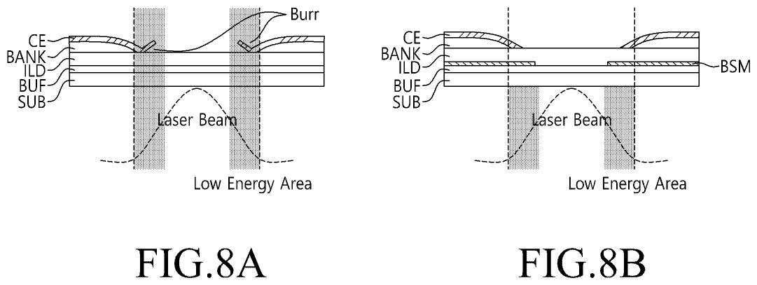

FIGS. 8A and 8B illustrate a comparison of a defect in which a metal layer is burred (e.g., an edge of the metal layer is raised) on the surface of the metal layer in an example where a shielding layer having a structure corresponding to a structure of an emission layer cutting pattern is present and an example where such a shielding layer is absent, in the display panel 110 according to aspects of the present disclosure.

Referring to FIGS. 8A and 8B, to form at least one emission layer cutting pattern ECP to prevent moisture from penetrating around a through hole TH where an optical electronic device 11 is located, laser beams can be radiated from under the display panel 110, and thereby, a valley of the emission layer cutting pattern ECP can be formed.

In this configuration, an energy intensity in a central area in energy distribution that represents the distribution of energy released from the incident laser beams can be the greatest, and the energy intensity can decrease in the form of a Gaussian function from the central area toward edge areas in the energy distribution.

Referring to FIG. 8A, even when a metal layer (e.g., the cathode electrode CE discussed above) disposed over the shielding layer corresponding to the central area in the energy distribution can be smoothly removed by the great energy intensity, since energy intensities in edge areas in the energy distribution can be low, a portion of the metal layer corresponding to each edge area in the energy distribution may not be smoothly removed, and a burr phenomenon in which an edge of the metal layer are raised can occur.

Referring to FIG. 8B, in one or more aspects, the display panel 110 can include a shielding layer BSM having an opening area smaller than an area where the metal layer over the shielding layer BSM is opened. According to this configuration, in the process where the laser beams are radiated to remove the metal layer, the burr phenomenon in which edges of the metal layer over the shielding layer BSM are raised in areas adjacent to, or in edge areas of, the laser beams can be prevented because some laser beams corresponding to low energy areas in the energy distribution are blocked by the shielding layer BSM.

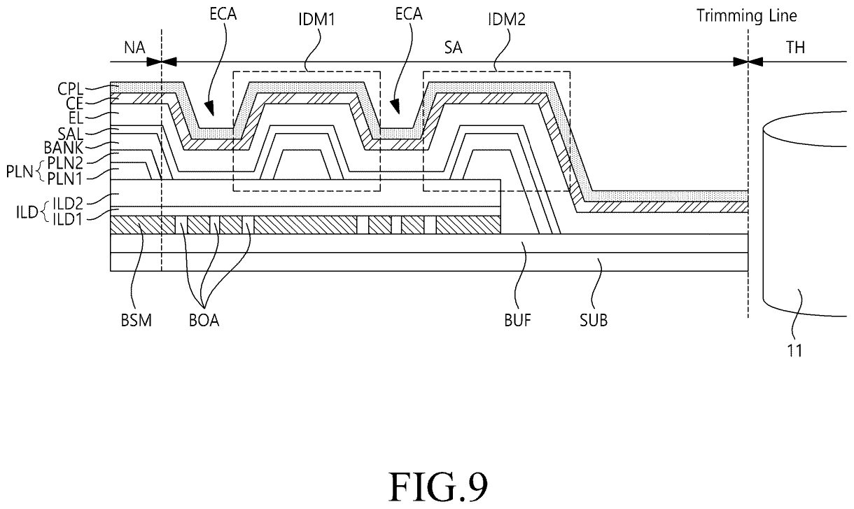

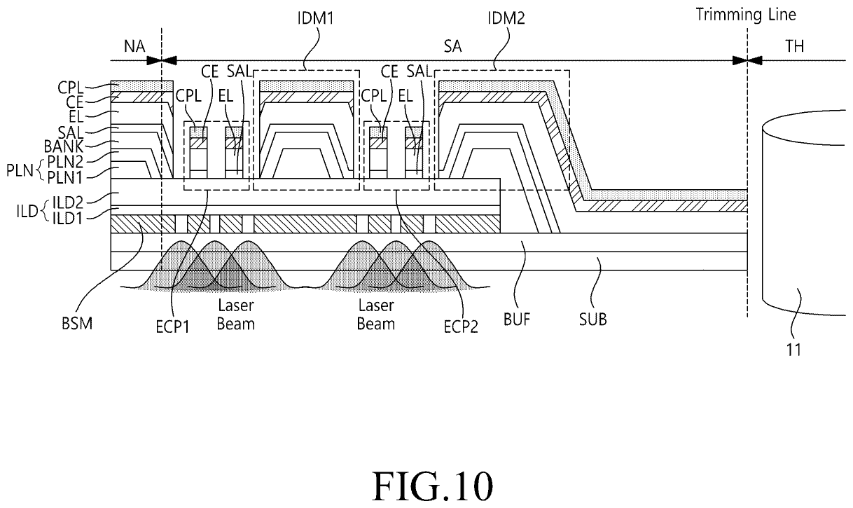

FIGS. 9 and 10 illustrate an example process of forming the display panel 110 according to aspects of the present disclosure.

Referring to FIG. 9, in one or more example embodiments, the display panel 110 can include at least one optical area OA disposed in the display area DA.

For example, a plurality of subpixels can be disposed in the at least one optical area OA. The at least one optical area OA can include a through hole TH and a surrounding area SA around the through hole TH.

At least one emission layer cutting pattern ECP can be disposed in the surrounding area SA to prevent moisture from penetrating through the through hole TH.

The through hole TH can be formed by removing a portion of the substrate SUB along a trimming line. The shape of the through hole TH can be circular, but aspects of the present disclosure are not limited thereto. For example, the shape of the through hole TH can have various shapes such as an oval, a square, a hexagon, or an octagon.

A buffer layer BUF can be disposed on a substrate SUB of the display panel 110. The buffer layer BUF can include a multi-buffer layer MBUF, a first active buffer layer ABUF1, and a second active buffer layer ABUF2.

In the surrounding area SA outside of the through hole TH, a shielding layer BSM corresponding to a structure of the at least one emission layer cutting pattern ECP can be disposed on the buffer layer BUF.

The shielding layer BSM can be a metal layer for effectively blocking energy released from laser beams. The shielding layer BSM can have a structure in which a plurality of shielding metals having different thermal conductivities are stacked.

A portion of the shielding layer BSM can be opened at a location corresponding to a valley of the at least one emission layer cutting pattern ECP. Thus, the shielding layer BSM can have the open area at the location corresponding to the valley of the at least one emission layer cutting pattern ECP.

An interlayer insulating layer ILD including a first interlayer insulating layer ILD1 and a second interlayer insulating layer ILD2 can be disposed on the shielding layer BSM.

To form at least one inner dam (IDM1 and/or IDM2) between the normal area NA and the through hole TH, a planarization layer PLN and a bank BANK can be disposed on the interlayer insulating layer ILD such that respective portions of the planarization layer PLN and the bank BANK protrude upwardly.

In one or more aspects, the at least one inner dam (IDM1 and/or IDM2) can be disposed only between emission layer cutting patterns ECP. In this implementation, the planarization layer PLN and the bank BANK can be removed in at least one emission layer disconnected area ECA where the at least one emission layer cutting pattern ECP is to be disposed.

A sacrificial layer SAL can be disposed such that it covers the at least one emission layer disconnected area ECA and the bank BANK. In one or more aspects, an emission layer EL, a cathode electrode CE, and a capping layer CPL can be sequentially stacked on the sacrificial layer SAL.

Referring to FIG. 10, to form the at least one emission layer cutting pattern ECP, laser beams can be radiated from under the display panel 110, and thereby, the sacrificial layer SAL and the layers stacked on the sacrificial layer SAL can be removed.

In this implementation, since the laser beams are allowed to be incident only through at least one open area BOA of the shielding layer BSM, respective portions of the sacrificial layer SAL, the emission layer EL, the cathode electrode CE, and capping layer CPL located in a corresponding valley of the at least one emission layer cutting pattern (ECP1 and/or ECP2) can be removed.

In contrast, a corresponding ridge of the at least one emission layer cutting pattern (ECP1 and/or ECP2) can be formed in a portion where the laser beams are blocked by the shielding layer BSM.

According to these configurations, since some laser beams corresponding to a low energy area in energy distribution released from the laser beams are blocked, by the shielding layer BSM, at boundaries of the valley included in the at least one emission layer cutting pattern (ECP1 and/or ECP2), the display device 100 can provide an effect or advantage of preventing the burr phenomenon of the cathode electrode CE caused by the laser beams corresponding to the low energy area.

In particular, when the shielding layer BSM includes multiple open areas BOA corresponding to a structure of the at least one emission layer cutting pattern (ECP1 and/or ECP2), some laser beams incident through each of the multiple open areas BOA overlaps with some laser beams incident through adjacent one or more other open areas BOA, and therefore, a low energy area in energy distribution released from laser beams can be reduced. As a result, the burr phenomenon of the cathode electrode CE caused by the low energy area in energy distribution released from laser beams can be further reduced.

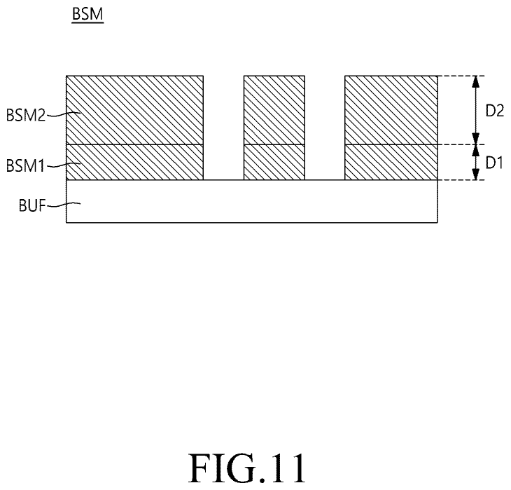

FIG. 11 is an example cross-sectional view of a shielding layer in the display panel 110 according to aspects of the present disclosure.

Referring to FIG. 11, in one or more example embodiments, at least one shielding layer BSM included in the display panel 110 can be located between a substrate SUB and an emission layer cutting pattern ECP.

In this implementation, the at least one shielding layer BSM can be a metal layer for effectively blocking a low energy area in energy distribution released from laser beams incident to form the emission layer cutting pattern ECP.

For example, the at least one shielding layer BSM can include a first shielding metal layer BSM1 and a second shielding metal layer BSM2 that have different thermal conductivities.

The first shielding metal layer BSM1 can include a metal having low thermal conductivity to directly block laser beams incident from under the first shielding metal layer BSM1. For example, the first shielding metal BSM1 can include titanium (Ti).

The second shielding metal layer BSM2 can be disposed on the first shielding metal layer BSM1 and include a metal having a higher thermal conductivity than the first shielding metal layer BSM1. For example, the second shielding metal layer BSM2 can include molybdenum (Mo).

In this implementation, the thickness D2 of the second shielding metal layer BSM2 can be greater than the thickness D1 of the first shielding metal layer BSM1.

According to the implementations discussed above, when the shielding layer BSM is disposed with a structure in which metal layers having different thermal conductivities are stacked, the burr phenomenon in which edges of the cathode electrode CE are raised at boundaries of the emission layer cutting pattern ECP can be reduced by effectively blocking some laser beams corresponding to a low energy area in energy distribution released from laser beams incident from under the shielding layer BSM.

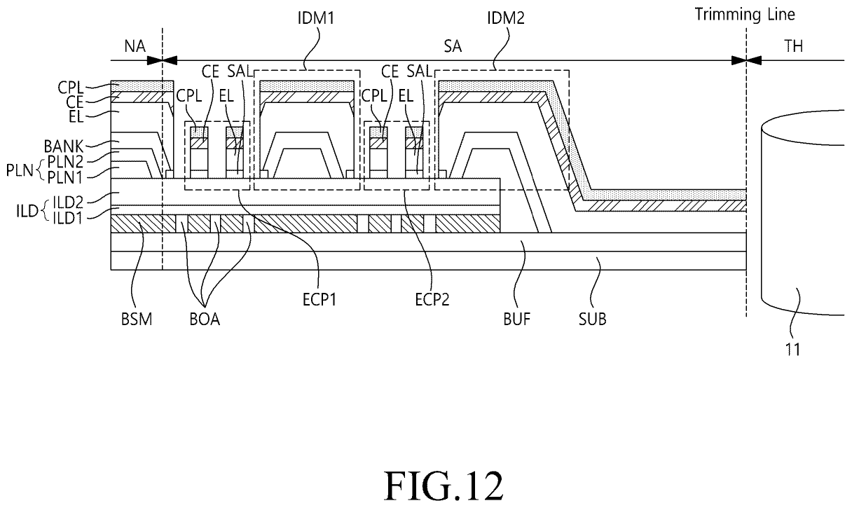

FIG. 12 is a cross-sectional view of another example structure of a surrounding area outside of a through hole in the display panel 110 according to aspects of the present disclosure.

Referring to FIG. 12, in one or more example embodiments, the display panel 110 can provide advantages of reducing the burr phenomenon of a metal layer and accurately forming at least one emission layer cutting pattern ECP through a shielding layer BSM with at least one open area corresponding to a structure of the at least one emission layer cutting pattern ECP.

In one or more aspects, the display panel 110 can include a sacrificial layer SAL formed only in at least one emission layer disconnected area ECA where the at least one emission layer cutting pattern ECP is to be disposed in a surrounding area SA outside of a through hole TH.

In one or more aspects, the sacrificial layer SAL can be disposed in both the normal area NA and the surrounding area SA, and in this implementation, an emission layer cutting pattern can be formed only in a desired area (e.g., an emission layer disconnected area ECA or a light emitting area).

In one or more aspects, an open area BOA of the shielding layer BSM can be formed to correspond to a valley of the emission layer cutting pattern ECP.

Therefore, when laser beams are radiated from under the shielding layer BSM, a valley of the emission layer cutting pattern ECP can be removed by some laser beams, and only a ridge of the emission layer cutting pattern ECP can be maintained in the surrounding area SA.

For example, the ridge of the emission layer cutting pattern ECP can have a structure in which the sacrificial layer SAL, an emission layer EL, a cathode electrode CE, and a capping layer CPL are sequentially stacked.

For example, the sacrificial layer SAL can be disposed only in an area where the emission layer cutting pattern ECP is located between a first inner dam IDM1 and a second inner dam IDM2. Therefore, the sacrificial layer SAL may not be disposed in the inner dams (IDM1 and IDM2) in the surrounding area SA and the normal area NA.

In one or more aspects, the emission layer cutting pattern ECP disposed in the display panel 110 can include only a valley where the emission layer EL is removed without a ridge.

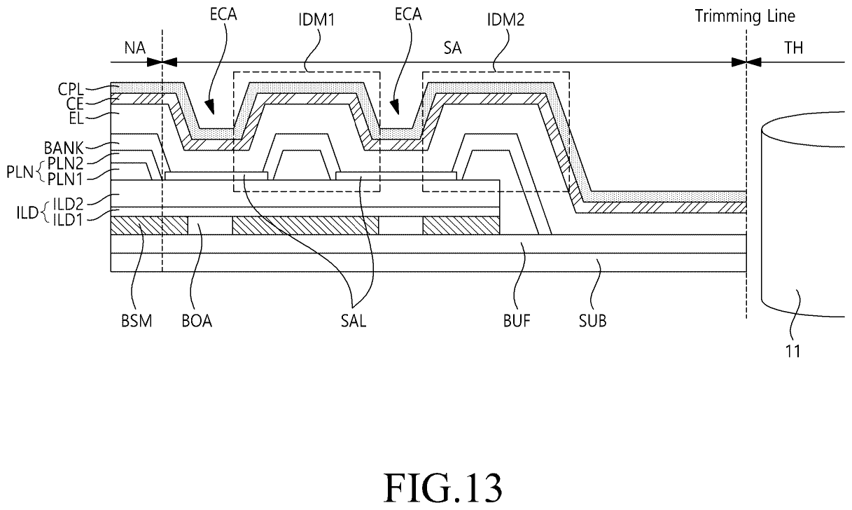

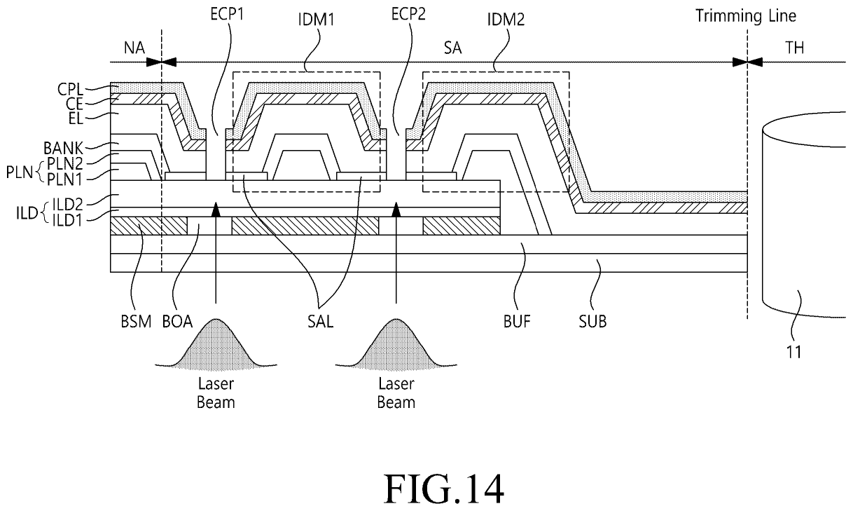

FIGS. 13 and 14 illustrate another example process of forming the display panel 110 according to aspects of the present disclosure.

Referring to FIG. 13, in one or more example embodiments, the display panel 110 can include at least one optical area OA disposed in the display area DA.

For example, a plurality of subpixels can be disposed in the at least one optical area OA. The at least one optical area OA can include a through hole TH and a surrounding area SA outside of the through hole TH.

In the surrounding area SA, at least one emission layer disconnected area ECA can be formed in which at least one emission layer cutting pattern ECP is to be disposed to prevent moisture from penetrating through the through hole TH.

The at least one emission layer cutting pattern ECP can include a valley in which an emission layer EL is removed. In this implementation, the at least one emission layer cutting pattern ECP may not include a ridge protruding upwardly.

The through hole TH can be formed by removing a portion of the substrate SUB along a trimming line. The shape of the through hole TH can be circular, but aspects of the present disclosure are not limited thereto. For example, the shape of the through hole TH can have various shapes such as an oval, a square, a hexagon, or an octagon.

A buffer layer BUF can be disposed on a substrate SUB of the display panel 110. The buffer layer BUF can include a multi-buffer layer MBUF, a first active buffer layer ABUF1, and a second active buffer layer ABUF2.

In the surrounding area SA outside of the through hole TH, a shielding layer BSM corresponding to a structure of the at least one emission layer disconnected area ECA can be disposed on the buffer layer BUF.

The shielding layer BSM can be a metal layer for effectively blocking energy released from laser beams. The shielding layer BSM can have a structure in which a plurality of shielding metals having different thermal conductivities are stacked.

The shielding layer BSM can include an open area at a location corresponding to a valley of the emission layer cutting pattern ECP.

An interlayer insulating layer ILD including a first interlayer insulating layer ILD1 and a second interlayer insulating layer ILD2 can be disposed on the shielding layer BSM.

To form at least one inner dam (IDM1 and/or IDM2) between the normal area NA and the through hole TH, a planarization layer PLN and a bank BANK can be disposed on the interlayer insulating layer ILD such that respective portions of the planarization layer PLN and the bank BANK protrude upwardly.

In one or more aspects, the at least one inner dam (IDM1 and/or IDM2) can be disposed in an area different from an area where the at least one emission layer disconnected area ECA is disposed.

A sacrificial layer SAL can be disposed such that it covers the at least one emission layer disconnected area ECA. In one or more aspects, an emission layer EL, a cathode electrode CE, and a capping layer CPL can be sequentially stacked on the sacrificial layer SAL.

Referring to FIG. 14, form the at least one emission layer cutting pattern ECP, laser beams can be radiated from under the display panel 110, and thereby, the sacrificial layer SAL and the layers stacked on the sacrificial layer SAL can be removed.

In this implementation, since the laser beams are allowed to be incident only through an open area BOA of the shielding layer BSM, respective portions of the sacrificial layer SAL, the emission layer EL, the cathode electrode CE, and capping layer CPL corresponding to the at least one emission layer disconnected area ECA can be removed.

According to these configurations, since some laser beams corresponding to a low energy area in energy distribution released from the laser beams are blocked, by the shielding layer BSM, at boundaries of the at least one emission layer disconnected area ECA, the display device can provide an effect or advantage of preventing the burr phenomenon of the cathode electrode CE due to the laser beams corresponding to the low energy area.

The example embodiments described above will be briefly described as follows.

According to the one or more example embodiments described herein, a display device can be provided that includes a display panel including a through hole located in a display area, an optical electronic device disposed such that at least part of the optical electronic device overlaps with the through hole, and a driving circuit configured to control the display panel, the display panel including at least one emission layer cutting pattern disposed in an surrounding area outside of the through hole to block moisture from entering the display area through the through hole, and a shielding layer located under the at least one emission layer cutting pattern and including at least one open area disposed at at least one location corresponding to the structure of the at least one emission layer cutting pattern.

In one or more aspects, the at least one emission layer cutting pattern can be an area where an emission layer included in a light emitting element is removed.

In one or more aspects, the display area can include an optical area in which the through hole and the emission layer cutting pattern are disposed, and a normal area in which subpixels are disposed outside of the optical area. In one or more aspects, the at least one the emission layer cutting pattern can include a first emission layer cutting pattern located in an area adjacent to the normal area, and a second emission layer cutting pattern located in an area adjacent to the through hole.

In one or more aspects, the display panel can include a substrate and a buffer layer disposed on the substrate, and the at least one open area of the shielding layer can be formed on the buffer layer.

In one or more aspects, the open area can be located to correspond to an area where the emission layer is removed.

In one or more aspects, the open area can have a width less than the emission layer cutting pattern.

In one or more aspects, the shielding layer can include a first shielding metal layer having a first thermal conductivity and a second shielding metal layer having a second thermal conductivity greater than the first thermal conductivity.

In one or more aspects, the second shielding metal layer can be disposed on the first shielding metal layer.

In one or more aspects, the first shielding metal layer can include titanium, and the second shielding metal layer can include molybdenum.

In one or more aspects, the second shielding metal layer can have a thickness greater than the first shielding metal layer.

In one or more aspects, the emission layer cutting pattern can include a valley where the sacrificial layer and the emission layer are removed.

In one or more aspects, the emission layer cutting pattern can include a ridge where the sacrificial layer and the emission layer are stacked, and a valley where the sacrificial layer and the emission layer are removed.

In one or more aspects, the surrounding area outside of the through hole can further include at least one inner dam where a planarization layer, a bank, the emission layer, and a cathode electrode are sequentially stacked.

In one or more aspects, the display panel can include a first emission layer cutting pattern, a first inner dam, a second emission layer cutting pattern, and a second inner dam, which are formed sequentially between the normal area and the surrounding area outside of the through hole.

According to the one or more example embodiments described herein, a display panel can be provided that includes a through hole located in a display area and allowing an optical electronic device to be disposed, at least one emission layer cutting pattern formed in an surrounding area outside of the through hole to block moisture from entering the display area through the through hole, and a shielding layer located under the emission layer cutting pattern and having at least one open area disposed at at least one location corresponding to the structure of the at least one emission layer cutting pattern.

The above description has been presented to enable any person skilled in the art to make, use and practice the technical features of the present invention, and has been provided in the context of a particular application and its requirements as examples. Various modifications, additions and substitutions to the described embodiments will be readily apparent to those skilled in the art, and the principles described herein can be applied to other embodiments and applications without departing from the scope of the present invention. The above description and the accompanying drawings provide examples of the technical features of the present invention for illustrative purposes only. For example, the disclosed embodiments are intended to illustrate the scope of the technical features of the present invention.

What is claimed is:

1. A display device comprising:
a display panel comprising a through hole disposed in a display area;
an optical electronic device disposed so that at least part of the optical electronic device overlaps with the through hole; and
a driving circuit configured to control the display panel,
wherein the display panel comprises:
an emission layer cutting pattern disposed in a surrounding area outside of the through hole, the emission layer cutting pattern extending from a normal area in which at least one subpixel is disposed, and disconnecting an emission layer; and
a shielding layer disposed under the emission layer cutting pattern and comprising at least one open area disposed at at least one location corresponding to a structure of the emission layer cutting pattern.

2. The display device of claim 1, wherein the emission layer cutting pattern comprises:
a first emission layer cutting pattern disposed in an area adjacent to the normal area; and
a second emission layer cutting pattern disposed in an area adjacent to the through hole.

3. The display device of claim 1, wherein the display panel further comprises:
a substrate; and
a buffer layer disposed on the substrate, and
wherein the at least one open area of the shielding layer is disposed on the buffer layer.

4. The display device of claim 3, wherein the at least one open area of the shielding layer is disposed in an area corresponding to an area in which the emission layer is removed.

5. The display device of claim 3, wherein the at least one open area of the shielding layer has a width less than a width of the emission layer cutting pattern in a vertical direction of a cross-sectional view of the display panel.

6. The display device of claim 3, wherein the shielding layer comprises:
a first shielding metal layer having a first thermal conductivity; and
a second shielding metal layer having a second thermal conductivity greater than the first thermal conductivity.

7. The display device of claim 6, wherein the second shielding metal layer is disposed on the first shielding metal layer.

8. The display device of claim 6, wherein the first shielding metal layer comprises titanium, and the second shielding metal layer comprises molybdenum.

9. The display device of claim 6, wherein the second shielding metal layer has a thickness greater than a thickness of the first shielding metal layer.

10. The display device of claim 1, wherein the surrounding area outside of the through hole comprises a sacrificial layer and the emission layer disposed on the sacrificial layer, and
wherein the emission layer cutting pattern comprises a valley where the sacrificial layer and the emission layer are removed.

11. The display device of claim 10, wherein the sacrificial layer is disposed only in the surrounding area outside of the through hole.

12. The display device of claim 1, wherein each of the normal area and the surrounding area outside of the through hole comprises a sacrificial layer and the emission layer disposed on the sacrificial layer, and
wherein the emission layer cutting pattern comprises:
a ridge in which the sacrificial layer and the emission layer are stacked; and
a valley in which the sacrificial layer and the emission layer are removed.

13. The display device of claim 1, wherein the surrounding area outside of the through hole further comprises at least one inner dam, and
wherein the at least one inner dam comprises:
a planarization layer;
a bank disposed on the planarization layer;
the emission layer disposed on the bank; and
a cathode electrode disposed on the emission layer.

14. The display device of claim 13, wherein the display panel comprises a first emission layer cutting pattern and a second emission layer cutting pattern disposed on a side of the at least one inner dam.

15. A display panel comprising:
a through hole disposed in a display area and configured to allow an optical electronic device to be disposed;
an emission layer cutting pattern disposed in a surrounding area outside of the through hole, the emission layer cutting pattern extending from a normal area in which at least one subpixel is disposed, and disconnecting an emission layer; and
a shielding layer disposed under the emission layer cutting pattern and having at least one open area disposed at at least one location corresponding to a structure of the emission layer cutting pattern.

16. The display panel of claim 15, wherein the surrounding area outside of the through hole comprises a sacrificial layer and the emission layer disposed on the sacrificial layer, and
wherein the emission layer cutting pattern comprises a valley where the sacrificial layer and the emission layer are removed.

17. The display panel of claim 16, wherein the sacrificial layer is disposed only in the surrounding area outside of the through hole.

18. The display panel of claim 15, wherein each of the normal area and the surrounding area outside of the through hole comprises a sacrificial layer and the emission layer disposed on the sacrificial layer, and
wherein the emission layer cutting pattern comprises:
a ridge in which the sacrificial layer and the emission layer are stacked, and
a valley in which the sacrificial layer and the emission layer are removed.
